(19) United States
(12) Patent Application Publication
(10) Pub. No.: US 2007/0096095 A1
(43) Pub. Date: May 3, 2007

(54) Test pattern for semiconductor device and method for measuring pattern shift

(75) Inventor: Chang Nam Kim, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu Electronics Co., Ltd.

(21) Appl. No.: 11/589,959

(22) Filed: Oct. 31, 2006

(30) Foreign Application Priority Data
Oct. 31, 2005 (KR) 10-2005-0102995

(51) Int. Cl. H01L 23/58

(52) U.S. Cl. 257/48

(57) ABSTRACT

There are provided a test pattern for a semiconductor device includes a buried layer formed on a surface of a substrate; a semiconductor layer formed on an entire surface of the substrate; and first and second high-concentration impurity regions formed in the surface of the semiconductor layer and electrically connected to the buried layer, wherein the first and second high-concentration impurity regions are misaligned. with the buried layer by a predetermined distance; measuring the current flowing through the test pattern in a first direction and a second direction, the first direction being perpendicular to the second direction; and calculating a shifted value of the buried layer from the measuring result.

### RELATED APPLICATION

This application is based upon and claims the benefit and priority of Korean Application No. 10-2005-0102995, filed on Oct. 31, 2005, the entire contents of which are incorporated herein by reference.

### TECHNICAL FIELD

The present invention relates to a method for fabricating a semiconductor device, and more particularly, to a test pattern for a semiconductor device and a method for measuring pattern shift which reduces measuring errors.

### BACKGROUND

There are many semiconductor processes requiring an epitaxial process. Particularly, semiconductor processes such as analog processes, high voltage processes, and image sensor processes require an epitaxial process to be performed in a fab process so that the desired semiconductor devices are integrated into a wafer.

Since the devices are susceptible to noise, buried layers are used to isolate the devices. Alternatively, a silicon-on-insulator (SOI) wafer process may be used.

When an epitaxial layer is used, the silicon (Si) layer generally has a uniform crystal lattice direction while it is formed causing a pattern shift of the epitaxial layer.

Subsequent layers are then formed using aligning methods. The alignment method used may significantly affect the isolation characteristics and thus could be a deterministic factor of the design rules. Specifically, appropriate control of the alignment allows for smaller design rules and reduced costs.

In general, a photo align mark is formed before performing an epitaxial process to form subsequent layers after forming the epitaxial layer. In such cases, a photo align mark, a junction isolation, or a pattern for forming a buried layer to make a low-resistance layer may be used.

The buried layer is typically used to simplify a semiconductor process. The processes of forming the buried layer will be described below.

FIGS. 1A to 1C are cross-sectional views illustrating a conventional method for forming a test pattern of a semiconductor device.

As shown in FIG. 1A, a first buffer oxide layer 22 is formed on a silicon substrate 21 and then selectively removed through photolithographic and etching processes to expose a predetermined portion of a surface of silicon substrate 21 thereby defining a buried region.

High-concentration n-type impurity ions are then injected and diffused into the exposed portion of silicon substrate 21 using first buffer oxide layer 22 as a mask, forming a first n⁺-type diffusion region 23 on the surface of silicon substrate 21, wherein first n⁺-type diffusion region 23 is a buried layer.

First buffer oxide layer 22 is then removed, and an epitaxial process is performed on the entire surface of silicon substrate 21 to form an epitaxial layer 24 on silicon substrate 21 having first n⁺-type diffusion region 23.

Subsequently, a second buffer oxide layer 25 is formed on epitaxial layer 24 and then selectively removed through photolithographic and etching processes to expose a predetermined portion of a surface of epitaxial layer 24.

High-concentration n⁺-type impurity ions are then injected and diffused into the exposed portion of epitaxial layer 24 using second buffer oxide layer 25 as a mask to form a second. n⁺-type diffusion region 26 on the surface of epitaxial layer 24. Second buffer oxide layer 25 is then removed.

In the test pattern of a conventional semiconductor device fabricated as described above, first n⁺-type diffusion region 23 formed as a buried layer is used as a photo align mark to align layers to be formed in subsequent procedures after forming epitaxial layer 24. The photo align mark, however, is shifted in a direction parallel to the surface of silicon substrate 21 due to the epitaxial process performed after first n⁺-type diffusion region 23 is formed.

Accordingly, subsequent layers are aligned with a corresponding offset according to the parallel shifted value of first n⁺-type diffusion region 23. Therefore, to determine the offset for the subsequent layers, the parallel shifted value is measured using a cross-section scanning electron microscopy (SEM) or a microscope at an initial development stage.

Values measured using the cross-section SEM or the microscope are obtained through the alignment pattern and the method described below. The use of SEM photographs, however, may cause measuring errors since it depends on visual measurements from SEM photographs.

After the shifted values of the test pattern, i.e., a width B of first n⁺-type diffusion region 23, a width C of second n⁺-type diffusion region 26, and a non-overlapping width A between first n⁺-type diffusion region 23 and second n⁺-type diffusion region 26, are measured using the SEM and the like, the resultant shift value is calculated by the equation, (A+B−C)/2.

Since it is difficult to test a high number of samples using the SEM and the like in measuring the shift of the test pattern, the shift value is measured based on several particular points. This may result in errors in sampling accuracy, and thus decrease the overall precision of the test.

### BRIEF SUMMARY

Accordingly, embodiments consistent with the present invention are directed to a test pattern for a semiconductor device and a method for measuring pattern shift which are capable of precisely defining an offset value of a subsequent layer by detecting a precise amount of pattern shift upon development, and for allowing feedback to a high-speed process by monitoring such pattern shift upon fabrication, by proposing a test pattern and a test method for measuring misalignment of an epitaxial layer at an initial development stage or at a post-development stage.

Consistent with an embodiment of the present invention, there is provided a test pattern for a semiconductor device comprising a buried layer formed on a surface of a substrate; a semiconductor layer formed on an entire surface of the substrate; and first and second high-concentration impurity regions formed in the semiconductor layer and electrically connected to the buried layer.

Consistent with another embodiment of the present invention, there is provided a method for measuring pattern shift in a semiconductor device, and the method comprises providing a test pattern, the test pattern comprising a buried layer formed on a surface of a substrate, a semiconductor layer formed on an entire surface of the substrate, and first and second high-concentration impurity regions formed in the surface of the semiconductor layer and electrically connected to the buried layer, wherein the first and second high-concentration impurity regions are misaligned with the buried layer by a predetermined distance; measuring the current flowing through the test pattern in a first direction and a second direction, the first direction being perpendicular to the second direction; and calculating a shifted value of the buried layer from the measuring result.

### BRIEF DESCRIPTION OF THE DRAWINGS

Advantages and features of the present invention will become apparent from the following description of embodiments given in conjunction with the accompanying drawings, in which:

FIGS. 1A to 1C are cross-sectional views illustrating a conventional method for forming a test pattern of a semiconductor device;

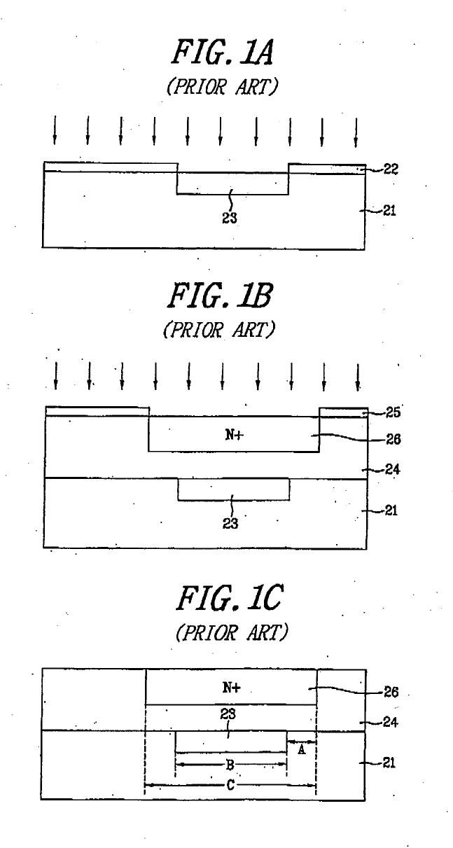

FIGS. 2A to 2C are cross-sectional views illustrating a method for fabricating a test pattern of a semiconductor device consistent with an embodiment of the present invention;

FIGS. 3A to 3C are plan views illustrating the test pattern of the semiconductor device fabricated through the process as shown in FIGS. 2A to 2C; and

FIG. 4 is a graph illustrating a result of measuring shift of a test pattern in a semiconductor device consistent with an embodiment of the present invention.

### DETAILED DESCRIPTION

Hereinafter, embodiments consistent with the present invention will be described in detail with reference to the accompanying drawings so that they can be readily implemented by those skilled in the art.

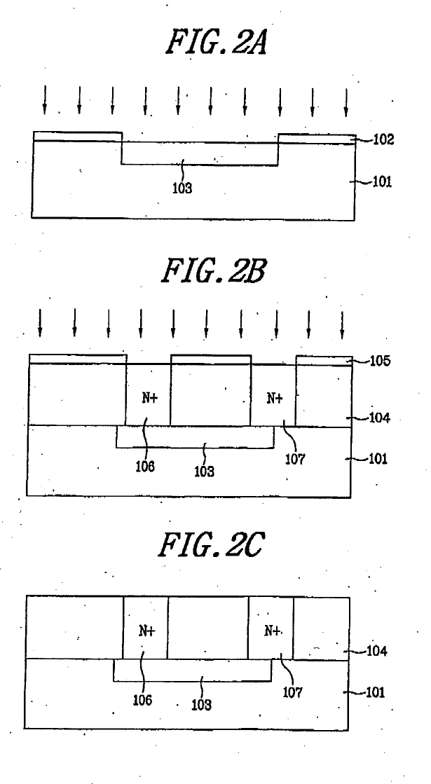

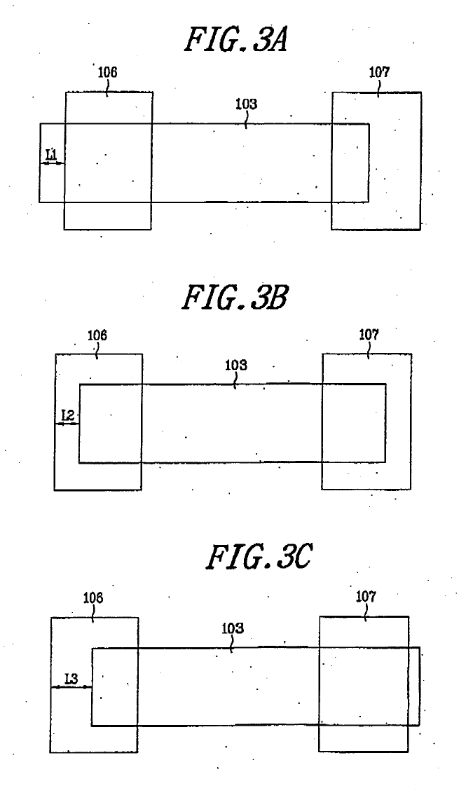

FIGS. 2A to 2C are cross-sectional views illustrating a method for fabricating a test pattern of a semiconductor device consistent with an embodiment of the present invention, and FIGS. 3A to 3C are plan views illustrating the test pattern of the semiconductor device. fabricated through the process as shown in FIGS. 2A to 2C.

As shown in FIG. 2A, a first buffer oxide layer 102 is formed on a silicon substrate 101 and then selectively removed through photolithographic and etching processes to expose a predetermined portion of a surface of silicon substrate 101 defining a buried region.

High-concentration n-type impurity ions are then injected and diffused into the exposed portion of silicon substrate 101 using first buffer oxide layer 102 as a mask, forming a first n⁺-type diffusion region 103 on the surface of silicon substrate 101, wherein first n⁺-type diffusion region 103 is a buried layer.

As shown in FIG. 2B, first buffer oxide layer 102 is removed, and an epitaxial process is performed on the entire surface of silicon substrate 101 to form an epitaxial layer 104 on silicon substrate 101 having first n⁺-type diffusion region 103.

Subsequently, a second buffer oxide layer 105 is formed on epitaxial layer 104 and selectively removed through photolithographic and etching processes to expose a predetermined portion of a surface of epitaxial layer 104.

POCL₃ doping or high-concentration n⁺-type impurity ion injection and diffusion is then performed on the exposed portion of epitaxial layer 104 using second buffer oxide layer 105 as a mask, forming second and third n⁺-type diffusion regions 106 and 107 in epitaxial layer 104. Second and third n⁺-type diffusion regions 106 and 107 are formed such that second and third n⁺-type diffusion regions 106 and 107 are misaligned with first n⁺-type diffusion region 103 by a predetermined distance.

Examples of second and third n⁺-type diffusion regions 106 and 107 misaligned with first n⁺-type diffusion region 103 are described below and illustrated in FIG. 3A to 3C.

In the case illustrated in FIG. 3A, second n⁺-type diffusion region 106 completely overlaps first n⁺-type diffusion region 103, which is used as an underlying buried layer, and is misaligned by a predetermined distance L1 at one side, and. third n⁺-diffusion region 107 partially overlaps first n⁺-type diffusion region 103.

In the case illustrated in FIG. 3B, both second and third n⁺-type diffusion regions 106 and 107 partially overlap first n⁺-type diffusion region 103, which is used as the underlying buried layer, and are misaligned by a predetermined distance L2 at one side.

In the case illustrated in FIG. 3C, second n⁺-type diffusion region 106 partially overlaps first n⁺-type diffusion region 103, which is used as the underlying buried layer, and third n⁺-type diffusion region 107 completely overlaps first n⁺-type diffusion region 103, and is misaligned by a predetermined distance L3 at one side.

As shown in FIG. 2C, second buffer oxide layer 105 is removed.

Consistent with an embodiment of the present invention, the shift amount is measured with the test patterns of the semiconductor device comprising first n⁺-type diffusion region 103 which is the buried layer used as the photo align mark, epitaxial layer 104, and second and third n⁺-type diffusion regions 106 and 107 formed in epitaxial layer 104, wherein second and third n⁺-type diffusion regions 106 and 107 overlap first n⁺-type diffusion region 103 in a different way for each test.

Generally, in the test pattern of the semiconductor device, first n⁺-type diffusion region 103 formed as the buried layer is used as the photo align mark to align subsequently formed layers after forming epitaxial layer 104. In such cases, the photo align mark is shifted in a direction parallel to the surface of silicon substrate 21 due to the epitaxial process performed after first n⁺-type diffusion region 103 is formed. The parallel shifted value is then measured.

Consistent with an embodiment of the present invention, the shift amounts of the test patterns are measured electrically and examined statistically. Thus, the accuracy of the measurement is increased.

Specifically, several test patterns can be obtained by electrically connecting first n⁺-type diffusion region 103, which is the buried layer, with second and third n⁺-type diffusion regions 106 and 107 formed in epitaxial layer 104 and making the diffusion regions intentionally misaligned, as shown in FIGS. 3A to 3C. That is, a number of test patterns can be formed which intentionally contain misalignments, for example, L1, L2, and L3, as shown in FIG. 3A to 3C.

Test patterns along the X-axis direction and test patterns along the Y-axis direction are fabricated.

When a voltage is applied to second and third n⁺-type diffusion regions 106 and 107 and then the current is measured using an electrical parameter tester, the current can be detected at a normal state where second and third n⁺-type diffusion regions 106 and 107 are connected to each other. The current may be converted to a resistance value.

Measuring and plotting the current or resistance values in a misalignment direction would show that such values on both sides are equivalent, resulting in a symmetrical curve. From this plotted curve, it can be recognized whether a center value of the symmetrical plot structure is shifted in a positive (+) or negative (−) direction. A distance from the center value on the plotted curve indicates a shifted amount of the pattern, which is used to determine an offset value of subsequent layers.

Furthermore, X-axis shift can be determined by fabricating X-axis based test patterns and measuring and plotting pattern shift thereof, and Y-axis shift can be determined by fabricating Y-axis based test patterns and measuring and plotting pattern shift thereof. This is, the X-axis shift and the Y-axis shift can be determined by performing the steps described above using current measurements in the X-direction and the Y-direction, respectively.

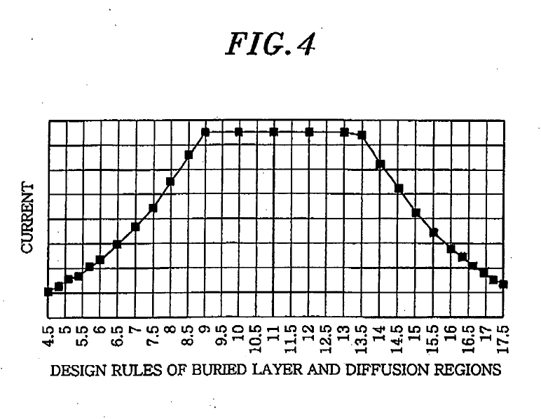

FIG. 4 is a graph illustrating a result of measuring shift of a test pattern in a semiconductor device consistent with an embodiment of the present invention.

It can be seen in FIG. 4 that the test pattern is not shifted. If the test pattern were shifted, the center of the plotted curve would be shifted in. one direction.

Since the test pattern for the semiconductor device consistent with an embodiment of the present invention uses heavily doped second and third n⁺-type diffusion regions 106 and 107, i.e., the deep n⁺ layers, the current or resistance can be measured using an electrical parameter tester during a fab process.

That is, the current or resistance is measured electrically after the deep n+layer is formed (i.e., after POCL₃ is doped or deep n⁺-ions are injected and diffused).

Because the symmetrical pattern is required, the current or the resistance values can be measured by an electrical parameter tester with a low precision.

As described above, the test pattern for the semiconductor device and the method for measuring pattern shift consistent with an embodiment of the present invention have the following advantages.

The pattern shift is measured electrically, unlike conventional methods of visually measuring pattern shift using, for example, an SEM. This can improve accuracy of measurements and reduce measuring errors.

The pattern shift can be also statistically measured using, for example, a full wafer map, unlike conventional methods that perform measurements only at several particular points. This can minimize sampling errors and precisely detect uniformity of a wafer subjected to an epitaxial process.

In a fabrication process, an electrical nondestructive test, not a destructive test, is possible. This can reduce costs.

While the invention has been shown and described with respect to the above embodiments, it will be understood by those skilled in the art that various changes and modifications may be made without departing from the spirit and scope of the invention as defined in the following claims.

What is claimed is:

1. A test pattern for a semiconductor device comprising:
a buried layer formed on a surface of a substrate;
a semiconductor layer formed on an entire surface of the substrate; and
first and second high-concentration impurity regions formed in the semiconductor layer and electrically connected to the buried layer.

2. The test pattern of claim 1, wherein the first and second high-concentration impurity regions partially overlap both sides of the buried layer.

3. The test pattern of claim 1, wherein the first high-concentration impurity region completely overlaps one side of the buried layer, and the second high-concentration impurity region partially overlaps the other side of the buried layer.

4. The test pattern of claim 1, wherein the first high-concentration impurity region partially overlaps one side of the buried layer, and the second high-concentration impurity region completely overlaps the other side of the buried layer.

5. The test pattern of claim 1, wherein the first and second high-concentration impurity regions are doped with POCL₃.

6. A method for measuring pattern shift in a semiconductor device, the method comprising:
providing a test pattern, the test pattern comprising:
a buried layer formed on a surface of a substrate,
a semiconductor layer formed on an entire surface of the substrate, and
first and second high-concentration impurity regions formed in the surface of the semiconductor layer and electrically connected to the buried layer, wherein the first and second high-concentration impurity regions are misaligned with the buried layer by a predetermined distance;
measuring the current flowing through the test pattern in a first direction and a second direction, the first direction being perpendicular to the second direction; and
calculating a shifted value of the buried layer from the measuring result.

7. The method for claim 6, further comprising converting the measured current into resistance.
